(19) United States
(12) Patent Application Publication
(10) Pub. No.: US 2006/0169198 A1
(43) Pub. Date: Aug. 3, 2006

(54) Phase delay element and method for producing a phase delay element

(76) Inventors: Karl-Heinz Schuster, Koenigsbronn (DE); Wolfram Reichel, Aalen (DE); Dietmar Staschke, Oberkochen (DE)

Correspondence Address: GRAY ROBINSON, P.A., 401 E. LAS OLAS BLVD., SUITE 1850, FT. LAUDERDALE, FL, 33301, US

(21) Appl. No.: 11/367,825

(22) Filed: Mar. 3, 2006

Related U.S. Application Data
(63) Continuation-in-part of application No. PCT/EP03/13214, filed on Nov. 25, 2003.

(30) Foreign Application Priority Data
Sep. 9, 2003 (DE) 103 41 378.2

(51) Int. Cl. H01L 21/322; C30B 15/14

(52) U.S. Cl. 117/2; 117/3

(57) ABSTRACT

In a method for producing a zeroth- or low-order phase delay element, in particular a phase delay element for wavelengths λ<200 nm, the phase delay element is formed from a birefringent crystalline material. A temporary carrier plate (1) is produced, which is provided with a plane-processed side (3). Afterwards, an anisotropic crystal plate (2) is produced, after which the temporary carrier plate (1) is connected to the anisotropic crystal plate (2) by means of a connecting means/connecting layer (6). A large part of the anisotropic crystal plate (2) is then separated away except from a residual layer, after which an end thickness of the anisotropic crystal plate (2) is reached by meaOns of further production and polishing methods. A second final carrier plate (8), which is produced by means of production and polishing methods, is directly connected to the anisotropic crystal plate (2), after which finally the temporary carrier plate (1) is separated or detached from the anisotropic crystal plate (2).

The invention relates to a method for producing a zeroth- or low-order phase delay element, in particular a phase delay element for wavelengths λ<200 nm, the phase delay element being formed from a birefringent crystalline material. Furthermore, the invention relates to a zeroth- or low-order phase delay element.

Phase delay elements are components which can be used to alter the state of polarization of the light in a defined manner. Zeroth-order phase delay elements, that is to say λ/4 elements and λ/2 elements, are required for semiconductor lithography with wavelengths λ<200 nm. Mirror lens objectives or projection objectives for semiconductor lithography without central shadowing with a polarization-optical splitter achieve their maximum transmission only if corresponding phase delay elements are available. Such phase delay elements should be of zeroth or low order since only then is it possible to achieve minimal angle-dependent phase delay changes.

The general prior art disclosed three solution approaches for producing such phase delay elements.

A first possibility is as follows: firstly an isotropic plate is subjected to pressure, tension, sheer or similar mechanical influencing variables, that is to say is mechanically strained, and, as a result, the original atomic layers present in the crystal lattice are spatially altered by the mechanical influence. The displacement of said atomic layers in the lattice causes the plate to become anisotropic. The anisotropy then permits generation of a phase delay of desired magnitude, in particular λ/4 zeroth order. In accordance with the condition:

$$Δ n = \frac{K \cdot λ}{d} ,$$

where Δn is the difference between nₒ and nₑ (nₒ is the refractive index of the ordinary ray and nₑ is the refractive index of the extraordinary ray), K represents the order of λ and is generally 0.25, d is the thickness of the plate and λ is the wavelength, for example for λ=157 nm and K=¼ and d=10 mm the value of Δn=3.9·10⁻⁶ μm is very small.

A further possibility for producing a phase delay plate consists in utilizing the intrinsic birefringence existing at wavelengths λ=193 nm and λ 157 nm in order to produce λ/4 phase delay elements. If these cannot be skillfully integrated by means of already existing lens elements, they would have to be provided by means of special plates made of CaF₂ (calcium fluoride) or BaF₂ (barium fluoride). What is disadvantageous about such a method is that these plates turn out to be undesirably thick even at λ=157 nm, and so they are not the preferred elements.

Furthermore, the general prior art discloses a third possibility, which prefers the use of birefringent crystals, such as, for example, MgF₂ (magnesium fluoride) or SiO₂ (silicon dioxide). The birefringence of the crystals MgF₂ or SiO₂, in relation to the strained plate from the first possibility for producing phase delay elements is so high that only a few μm of the thickness of the plate are achieved instead of a thickness in the cm range for a zeroth-order phase delay element, so that the thickness of the anisotropic crystal has the dimension of a thin film. Since specific minimum sizes of the phase delay element, such as format 70×160 mm or diameter 180 mm, are expected, in lithography, it is difficult to produce or handle such a thin film. Any extremely small external disturbance, for example a movement of air, would destroy the film and thus make it unusable. Consequently, it is an object of the invention to provide a method for producing a zeroth- or low-order phase delay element for wavelengths in the range λ<200 nm which achieves a thin, handleable and stable phase delay element in a large format or diameter.

According to the invention, the object is achieved by means of a method for producing a phase delay element according to claim 1.

According to the invention, a temporary carrier plate is connected to an anisotropic crystal plate. Afterward, a large part of the anisotropic crystal plate is separated away except for a residual layer and processed to an end thickness by means of production and polishing methods. A further step then consists in a second final carrier plate being directly connected to the anisotropic crystal plate and, afterward, the temporary carrier plate being separated or detached from the anisotropic crystal plate. Such a method now makes it possible to produce a thin phase delay element in a large format or diameter which does not become inoperative in the event of extremely small ambient influences. Consequently, having the zeroth order means that angle-dependent phase delay changes remain minimal.

Furthermore, it may advantageously be provided that the temporary carrier plate is connected to the anisotropic crystal plate by means of cementing. In this case, it is of particular importance that a cement or a connecting material should be one which has the ability to harden and ensure the connection and also releases its connection again under specific conditions.

An advantageous refinement of the invention may furthermore provide for the second final carrier plate to be connected to the anisotropic crystal plate by means of a wringing. The ringing onto the final carrier plate is a very good possibility for λ/4 plates made of MgF₂ in order to produce a thin phase delay element of this type which satisfies the requirements of preferably 157 nm lithography.

A phase delay element according to the invention is specified in claim 18.

The advantage of such a phase delay element according to the invention is that, in particular for the use of the phase delay element in projection objectives for semiconductor lithography which have a very high photoconductance and are operated with wavelengths of λ<200 nm, the phase delay element can be produced such that it is extremely thin with a large diameter and is light-transmissive when used at wavelengths of λ<200 nm. The plastics and films used hitherto cannot be used for such wavelengths since they are opaque to this type of light or become unusable due to the effect of light.

Exemplary embodiments of the invention are explained in more detail below in principle with reference to the drawings.

In the figures:

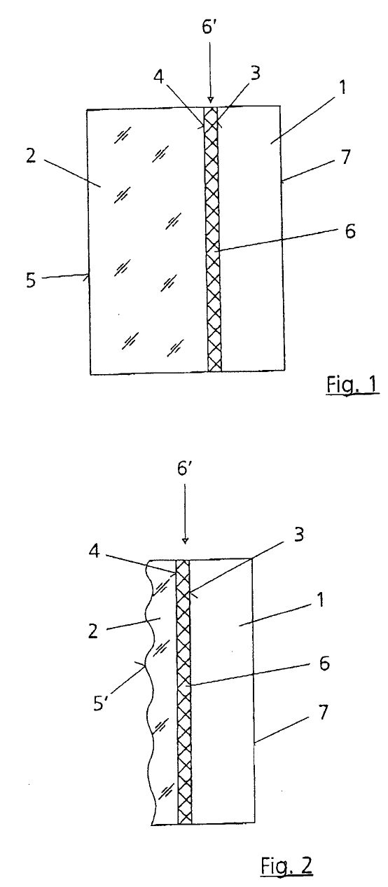

FIG. 1 shows an illustration of a temporary carrier plate in connection with a crystal plate;

FIG. 2 shows an illustration of the carrier plate illustrated in FIG. 1 in connection with the crystal plate, a large part of the crystal plate having been separated away;

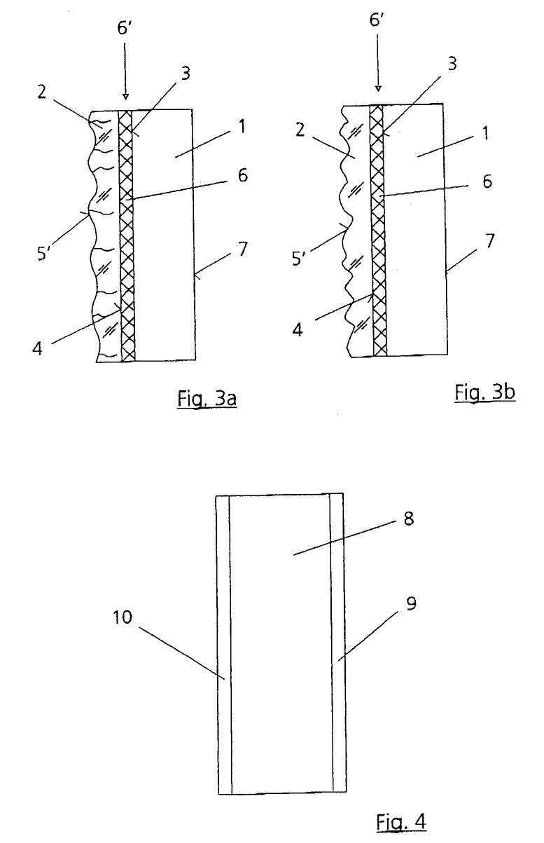

FIGS. 3a and 3b show illustrations of the carrier plate which can be seen in FIG. 2 with the crystal plate, with depth damage indicated and after the removal of the depth damage from the crystal plate;

FIG. 4 shows an illustration of a second final carrier plate provided with an adhesion layer and an antireflection coating layer;

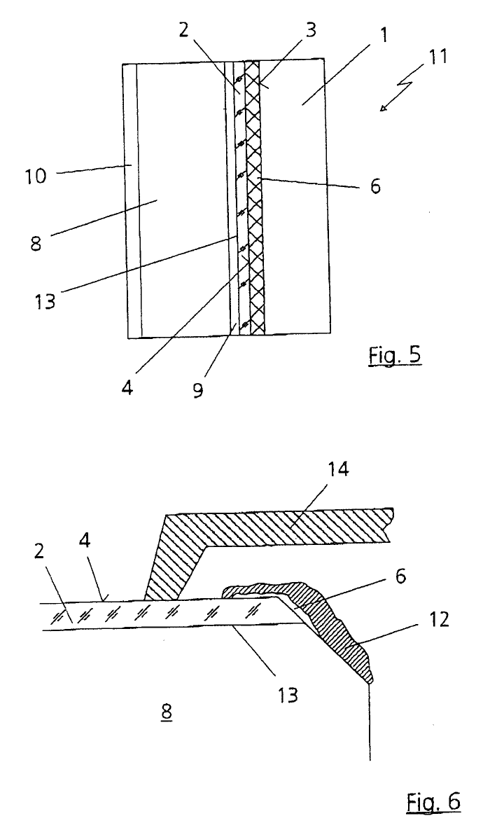

FIG. 5 shows an illustration of the temporary carrier plate and of the crystal plate in connection with the final carrier plate illustrated in FIG. 4;

FIG. 6 shows an illustration of a completed phase delay element; and

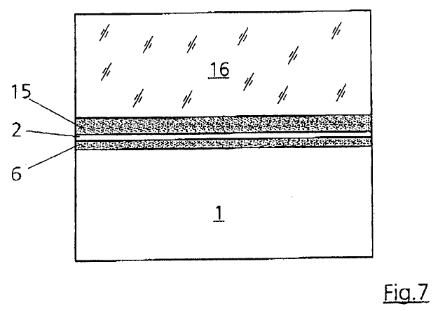

FIG. 7 shows an illustration of the anisotropic crystal plate in connection with an additional temporary carrier plate.

The following method is employed for producing crystalline zeroth- or low-order phase delay elements. A temporary carrier plate 1, serving as an auxiliary plate, is produced from a crystalline, isotropic material, for example from CaF₂ (calcium fluoride), or an amorphous material for example SiO₂ (silicon dioxide), as illustrated in FIG. 1. The temporary carrier plate 1 should as far as possible be free of stress birefringence, intrinsic contributions being present in crystals in the deep UV region. Therefore, it is recommendable to carry out measurements e.g. at 633 nm. The temporary carrier plate 1 is provided with a very well plane processed and thoroughly polished side or area 3.

A crystal plate 2 produced from an anisotropic crystal for example comprising SiO₂, MgF₂ (magnesium fluoride) or LaF₃ (lanthanum fluoride), referred to hereinafter as crystal plate 2, is likewise produced and should have a birefringence. Outer areas 4 and 5 of the anisotropic crystal plate 2 have been processed planar very well and have a very good plane parallelism. The crystal plate 2 is a uniaxial crystal whose orientation is described by an optical crystal axis. The optical crystal axis is not perpendicular to the plane areas 4 or 5, but rather lies ideally in the plate plane, namely parallel to the planar outer areas 4 and 5. One of the two outer areas 4 and 5 satisfies the general and customary specifications for 193 nm or 157 nm lithography with regard to microroughness, cleanness and area fit. The outer area 4, which has the prerequisite for microlithography in this exemplary embodiment, should be completely free of depth damage.

The temporary carrier plate 1 and the anisotropic crystal plate 2 are then connected to one another by means of a connecting layer 6, preferably by means of a cementing which is introduced into a connecting gap 6′ between the outer area 4 and the area 3, FIG. 1 illustrating the temporary carrier plate 1 already in connection with the crystal plate 2. Thermal cement is preferably used as connecting means for the connecting layer 6. In this case, it is important to use a connecting means which has the ability to harden and keep the connection stable, and which can subsequently be detached again from the temporary carrier plate 1 and the crystal plate 2. The connection should be effected as far as possible with a parallel connecting gap 6′. Equally, the connecting gap 6′ should be kept as thin as possible in order that the thermal cement as connecting means acquires greater load-bearing capacity. A complete parallelism of the connecting gap 6′ with respect to the temporary carrier plate 1 and the crystal plate 2 is not to be expected in practice, however. This remains without any disadvantages, however, by virtue of the further procedure described below.

In this case, it is advantageous to use slowly hardening thermal cement as connecting means, which thermal cement, in order to avoid stresses, is completely crosslinked and of good mechanical stability after a long hardening time, e.g. 5 days. Furthermore, the connection should as far as possible be free of blisters. The connecting gap 6′ may be checked in particular by means of a monochromatic illumination e.g. with the light from a mercury vapor lamp.

In this case, the temporary carrier plate 1 and the crystal plate 2 may be provided with steep chamfers; the crystal plate 2, however, should not have any chamfers or damage; this can be achieved e.g. by polishing the periphery.

An outer area 7 of the temporary carrier plate 1, which has previously only been worked on primarily, is processed as well as possible with regard to plane parallelism with respect to the outer area 5 of the crystal plate 2 and fully polished as a planar area. Consequently, the two areas 4 and 5 geometrically form a plane-parallel plate, the area 4 connected to the connecting layer 6 likewise being plane-parallel to the outer area 7. By means of a separating method, for example using a diamond-impregnated saw wire, a large part of the anisotropic crystal plate 2 is separated off or removed accept for a residual layer of a few millimeters. A residual thickness of the crystal plate 2 of about 1 to 2 mm on the connecting layer 6 is advantageous in this case.

FIG. 2 shows the connection of the temporary carrier plate 1 to the crystal plate 2 as illustrated in FIG. 1, but here the large part of the crystal plate 2 has been separated off. The separated-off part of the crystal plate 2 can be reused for producing phase delay elements. This is advantageous in so far as an many phase-delay elements of this type as possible can be produced from a relatively expensive, rare and correspondingly high-quality crystal.

The thus newly processable or produced area 5′ of the anisotropic crystal plate 2 is then preprocessed by further production and polishing methods, for example by lapping with loose abrasive grain, extremely gently parallel to the outer area 7 of the temporary carrier plate 1. With continuous monitoring of the parallelism, the thickness of the birefringent crystal plate 2 is reduced further or the processable area 5′ is polished down to an end thickness. By performing a plurality of lapping steps, the lapping granularity is continually reduced as the thickness decreases. By means of such a lapping process the depth damage in the crystal plate 2 is kept small to a certain extent.

The depth damage, which is illustrated more clearly in FIG. 3a, must not reach the provided layer of the crystal plate 2 having a residual thickness of a few μm. In order to eliminate the depth damage, single or multiple etching can be performed. Therefore, interposed etching steps using hydrofluoric acid (HF), for example, are highly advantageous. The etching method is performed in each case between the individual lapping steps in order to etch out the cracks which occur and which have penetrated deep in to the crystal plate 2. Such cracks result in the build up of compressive stresses, which are released again by the use of hydrofluoric acid in the etching method. The stress on the material is thereby relieved again. During the depth etching, the edge region of the crystal plate 2 with the connecting layer 6 is additionally protected by means of a paste that is resistant to hydrofluoric acid, such as soft waxes.

In FIG. 3b, the outer area 5′ of the crystal plate 2 has already been freed from the depth damage by means of such etching steps. An end thickness, for example of 4 μm of the anisotropic crystal plate 2, should ultimately be free of depth damage. For this reason, a relatively large amount should be polished away here as well, as previously in the case of the opposite outer area 7 of the temporary carrier plate 1. The end thickness of the crystal plate 2 depends on whether a λ/4 or λ/2 plate is required, the end thickness of the crystal plate 2 likewise depending on the wavelength λ used and on αn, which represents the difference between nₒ and nₑ, where nₒ represents the isotropic refractive index of the birefringent crystal 2 and nₑ represents the anisotropic refractive index of the birefringent crystal 2. The polishing need not necessarily be carried out using pitch, it likewise being possible, in a particularly advantageous manner, to use synthetic polishing carriers since the latter are not deposited into the connecting layer 6. For SiO₂ it is possible to use Desmopan as polishing carrier, for MgF₂ it is likewise possible to use Desmopan or else medium-hard pitch. Modern methods such as magnetorheological polishing (MRF), the outer area 5′ being polished by means of a fluid whose viscosity is increased in the magnetic field, also permit a constant removal. The particular advantage in this case is that only very small mechanical forces act on the thin crystal plate 2 or the outer area 5′ since extensive contact is not made. The “robot polishing” method could likewise be used here, and a small polishing wheel being used for polishing.

The crystal plate thickness is monitored first of all purely mechanically, for example by means of mechanical linear encoders, by careful measurement and logging of each thickness reached in the overall plate comprising temporary carrier plate 1, connecting layer 6 and crystal plate 2 after each individual step. Accuracies of a few 1/10 μm can thus be achieved given constant temperature regulation during the thickness measurement.

It is advantageous in this connection to effect constant temperature regulation, e.g. uniformly at 22° C. or, as in some optics workshops, usually 25° C. This is necessary since the anisotropic crystal plate 2 has a significantly higher thermal expansion than the temporary carrier plate 1. It is only after the relatively small thickness of a few μm has been reached for the anisotropic crystal plate 2 that this narrow temperature specification is relaxed. The small expansion of the temporary carrier plate 1, e.g. quartz glass at 0.5×10⁻⁶ or titanium dioxide quartz glasses with even significantly smaller expansions, is now fully manifested. The thin anisotropic crystal plate 2 fully follows the temporary carrier plate 1 despite a higher coefficient of expansion in the lateral geometry. Perpendicular to this, of course, the anisotropic crystal plate 2 is free, but this has no disadvantageous effect on account of its small thickness. If the temporary carrier plate 1 was cleanly mechanically measured prior to cementing with regard to thickness, wedge error and the azimuth thereof, a high degree of correspondence is apparent between the phase delay from the optical measurement and the geometrical thickness of the anisotropic crystal plate 2. The unknown thickness of the connecting layer 6 can be calculated by measuring exclusively plane-parallel components prior to cementing.

An accurate and additional monitoring is afforded by methods which determine the birefringence of the overall package of the temporary carrier plate 1, connecting layer 6 and birefringent crystal plate 2. Such methods generally measure the phases of the two components of the light which passes through the overall plate. Phase compensators or else λ/4 plates are used as scales in this case. Interferometers would likewise be possible as well, which work with different directions of polarization and which measure or determine the phases under different directions of polarization.

FIG. 4 illustrates a second, final carrier plate 8, which is produced by means of production and polishing methods and which is as isotropic as possible except for unavoidable proportions of intrinsic birefringence in the case of crystals and at operating wavelengths. It is expedient, before application of additional layers, to extensively determine the phase differences of the final carrier plate 8 according to magnitude and direction. The measurement results obtained for the final carrier plate 8 are subtracted from the result of the package measurement comprising temporary carrier plate 1, connecting layer 6 and anisotropic crystal plate 2. The phase delayed values of the birefringent crystal plate 2 thus remain. If visible light, for example with a wavelength λ of 632.8 nm or 543 nm from an He—Ne laser, is chosen, for instance, for the phase delay, the geometrical thickness of the final carrier plate 8 is calculated depending on the material, for example MgF₂, SiO₂ or LaF₃. The refractive index profiles of nₒ and nₑ, in particular at λ=157 nm, and at λ=193 nm, are used to determine the difference between nₒ and nₑ over the wavelength of the crystal plate 2. The effective phase difference is calculated from the following formula:

$${K}_{( λ )} = \frac{Δ n ( λ ) \cdot d}{λ} ,$$

where K represents the order of λ and is generally 0.25, Δn is the difference between nₒ and nₑ, d is the thickness and λ is the wavelength. At a wavelength of λ=157 nm and with the use of CaF₂ as final carrier plate 8, the intrinsic birefringence of CaF₂ should be added vectorially. The overall plate comprising the final carrier plate 8 and the crystal plate 2 is intended to achieve a defined phase delay of about λ/4 as a result.

After achieving the desired phase difference for the crystals MgF₂ or LaF₃, an oxidic adhesion layer 9, for example an SiO₂ or Al₂O₃ (Aluminum oxide) layer, is applied or vapor-deposited onto the second final carrier plate 8. This is not necessary for crystals such as silicon dioxide (SiO₂) since SiO₂ can be permanently wrung even without an adhesion layer 9. It is very probable that, in particular, MgF₂ or other fluorine-containing substrates can scarcely be permanently wrung without such an adhesion layer 9.

For the wavelength λ=193 nm, preferably vitreous silicon dioxide may be used as final carrier plate 8, and for a wavelength λ=157 nm the final carrier plate 8 may be formed for calcium fluoride (CaF₂). A low-stress antireflection coating layer 10 for the respective useful wavelength has already been applied to the final carrier plate 8 on a side which is not provided with the adhesion layer 9. An adhesion layer, for example made of Al₂O₃ or SiO₂, is likewise recommended for the final carrier plate 8 made of CaF₂. The thus finished processed final carrier plate 8 for the birefringent crystal plate 2 has outer areas worked plane-parallel to one another.

Under working conditions of high purity, the cleaned second final carrier plate 8 is subsequently connected to the anisotropic crystal plate 2, preferably by wringing 13, as is illustrated in FIG. 5. An overall system 11 produced in this way is then heated very gently. For a wavelength λ=157 nm, in particular, it is advantageous if the temporary carrier plate 1 and the final carrier plate 8 each have the same expansion since only mechanically sensitive crystals are provided here. This means that the two carrier plates 1 and 8 may comprise calcium fluoride, for example. However, it would also be possible for the two carrier plates 1 and 8 not to comprise the same material. If the transmission of amorphous silicon dioxide is able to improve further at the wavelength λ=157 nm, in a manner similar to that at the wavelength λ=193 nm, then the temporary carrier plate 1 and the final carrier plate 8 may in each case also comprise amorphous silicon dioxide.

Under the influence of heat, which means after the softening temperature of the connecting layer 6 has been reached, the temporary carrier plate 1 and the anisotropic crystal plate 2 which is connected to the second final carrier plate 8 via the wringing 13 are carefully sheared relative to one another and finally separated or detached from one another. In this case, the temperature is respectively to be chosen to be high enough to enable the shearing with minimal introduction of force. The separation of the temporary carrier plate 1 from the anisotropic crystal plate 2 is preferably effective in a uniformly temperature-regulated furnace with a monitored shear force. A temperature difference which is harmful for the crystals and which is caused by moving air, for example, would be expected outside the furnace. In the same way as previously the separated-off large part of the crystal plate 2, the temporary carrier plate 1 can be reused after cleaning. The final carrier plate 8 with the wrung-on birefringent crystal plate 2 is then carefully cooled down to room temperature in the furnace. In this case, particular care must be taken to ensure that a slow cooling rate is provided for CaF₂.

Afterward, a resist layer 12, in particular a two-component resist, having a thickness of about 1 to 2 mm is applied to the edge region of the crystal plate 2, as illustrated in FIG. 6. The resist layer 12 is preferably resistant to acetone or alcohol. Afterward, the surface 4 of the crystal plate 2 is cleaned anhydrously, this being carried out manually using high-purity acetone. After cleaning, the production of the phase delay element is complete. A small edge region remains, however, which should be covered against undesirable UV radiation when used in a projection objective in order that the region of the wringing 13 is not at any time exposed to attack by a liquid. A radiation protection 14 protects the region against the undesirable UV radiation.

If organic substances cannot be tolerated at any time, since instances of internal out-gassing are feared in a lithography projection objective, the edge region of the crystal plate 2 is removed. For this purpose, beveling away is effected by means of a dry process, for instance by means of a slowly running linen grinding belt in free restraint and fine granularity.

In one advantageous variant of the method according to the invention, handling the completed anisotropic crystal plate 2 is facilitated by virtue of the fact that after the end thickness of the anisotropic crystal plate 2 has been reached, an additional temporary carrier plate 16 is connected to the anisotropic crystal plate 2 by means of a thick cement layer 15 and the additional temporary carrier plate 16 is removed after the removal of the temporary carrier plate 1. This variant of the invention is described in detail below.

The anisotropic crystal plate 2 which has been completed after the various processing steps with regard to thickness and parallelism and has been cemented onto the temporary carrier plate 1 is once again cemented onto the additional temporary carrier plate 16 by the finished-processed side. In this case, this further cementing fulfills a completely different task from that of the preceding cementing. The first cementing should be as thin as possible, parallel and have a high modulus of elasticity. This first cementing is intended to bring the extremely thin anisotropic crystal plate 2 into a unit with the temporary carrier plate 1. This enables the anisotropic crystal plate 2 to be exposed to the forces of precision-optical processing. After this processing has been practically concluded, a new task arises, namely of securely storing the anisotropic crystal plate 2 until the first hard and thin cementing is removed.

The second cementing is chosen to be significantly thicker than the first. The consequence of this is that—presupposing an appropriately chosen chemical composition—it can readily be resolved by means of a solvent.

FIG. 8 shows the arrangement present after this method step. The anisotropic crystal plate 2 is connected to the temporary carrier plate 1 by means of the connecting layer 6. On the side remote from the connecting layer 6, the anisotropic crystal plate 2 is connected to the additional temporary carrier plate 16 by means of a further cement layer 15—which is significantly thicker than the connecting layer 6.

When cementing on the additional temporary carrier plate 16, an adaptation of the geometrical parameters of the plates is expedient. The temporary carrier plate 1 is subsequently separated by mechanical separation close to the connecting layer 6. In the further course of the procedure, the residues of the temporary carrier plate 1 are removed for example by lapping until the connecting layer 6 is reached. If the connecting layer 6 is very thin, the lapping abrasive must be chosen to be correspondingly fine in order not to permit any damage to the anisotropic crystal plate 2. After the removal of the temporary carrier plate 1, the connecting layer 6 is removed by means of manual cleaning with a solvent. In this case, all the cleaning movements on the anisotropic crystal plate 2 always proceed from the inner side outwardly over the edge of the anisotropic crystal plate 2.

Afterward, the anisotropic crystal plate 2 is actually wrung onto the final carrier plate 8. This can be effected comparatively safely since the thin anisotropic crystal plate 2 is cemented mechanically stably on the additional temporary carrier plate 16. Clean and as far as possible force-free wringing is advantageous in this case. Any contamination which is introduced during the wringing operation raises the thin anisotropic crystal plate 2 later. Although this does not change the phase delay, it leads to altered transmission conditions locally. After wringing has been effected, the additional temporary carrier plate 16 is separated from the anisotropic crystal plate 2 by means of a solvent.

In order that the solvent does not penetrate into the wringing, the additional temporary carrier plate 16 may be provided with openings via which the solvent penetrates. Before the solvent advances as far as the wringing, the cementing has already been chemically softened and attacked from the inner side. The fine channels are subsequently freed of the solvent by means of dry air. After the solvent has approximately completely dried off, the now mechanically resistanceless cementing is removed by rotation or shearing.

Finally, the thin anisotropic crystal plate 2 is cleaned manually, e.g. with acetone from the outer side inward. Momentary contact with the solvent is permissible since the wringing automatically frees itself of the penetrated solvent in the case of a small degree of wetting. This does not hold true for lengthy contact with a solvent, which can lead to a complete stripping away of the crystalline plate.

The phase delay element thus produced by the method described achieves a crystal diameter or its largest length extent of at least 100 000 times, in particular at least 250 000 times, the crystal thickness.

We claim:

1. A method for producing a zeroth- or low-order phase delay element, in particular a phase delay element for wavelengths λ<200 nm, the phase delay element being formed from a birefringent crystalline material,
a) a temporary carrier plate (1) being produced, which is provided with a plane-processed area (3),
b) an anisotropic crystal plate (2) being produced, after which
c) the temporary carrier plate (1) is connected to the anisotropic crystal plate (2) by means of a connecting layer (6), after which
d) a large part of the anisotropic crystal plate (2) is separated away except for a residual layer, after which
e) an end thickness of the anisotropic crystal plate (2) is reached by means of further production and polishing methods, after which
f) a second final carrier plate (8), which is produced by means of production and polishing methods, is connected to the anisotropic crystal plate (2), and after which
g) finally the temporary carrier plate (1) is separated or detached from the anisotropic crystal plate (2).

2. The method as claimed in claim 1, characterized in that the temporary carrier plate (1) is produced from a crystalline or an amorphous material.

3. The method as claimed in claim 1, characterized in that two outer areas (4, 5) of the anisotropic crystal plate (2) are embodied as plane-parallel outer areas.

4. The method as claimed in claim 1, characterized in that the temporary carrier plate (1) is connected to the anisotropic crystal plate (2) by means of cementing.

5. The method as claimed in one of claims 1, 3 or 4, characterized in that a preprocessing of a processable area (5′) of the anisotropic crystal plate (2) is performed by lapping, after which the processable area (5′) is polished down to the end thickness.

6. The method as claimed in claim 5, characterized in that a plurality of lapping steps are performed for the preprocessing of the processable side (5′).

7. The method as claimed in claim 6, characterized in that an etching method is in each case used to prevent depth damage between the lapping steps.

8. The method as claimed in claim 1, characterized in that an adhesion layer (9) is applied to the second final carrier plate (8).

9. The method as claimed in claim 8, characterized in that an SiO₂ or Al₂O₃ layer (9) is applied to the second final carrier plate (8).

10. The method as claimed in claim 8, characterized in that an antireflection coating layer (10) is applied to the second final carrier plate (8) on a side that is not provided with the adhesion layer (9).

11. The method as claimed in claim 1, characterized in that the second final carrier plate (8) is connected to the anisotropic crystal plate (2) by means of a wringing (13).

12. The method as claimed in claim 1, characterized in that the temporary carrier plate (1) is separated from the anisotropic crystal plate (2) under the influence of heat.

13. The method as claimed in claim 1, characterized in that a resist layer (12) is applied on an edge region of the anisotropic crystal plate (2).

14. The method as claimed in claim 1, characterized in that after the end thickness of the anisotropic crystal plate (2) has been reached, an additional temporary carrier plate (16) is connected to the anisotropic crystal plate (2) by means of a thick cement layer (15) and the additional temporary carrier plate (16) is removed after the removal of the temporary carrier plate (1).

15. The method as claimed in claim 14, characterized in that that side of the temporary carrier plate (1) which is remote from the anisotropic crystal plate (2) is processed in plane-parallel fashion with respect to that side of the anisotropic crystal plate (2) which is remote from the temporary carrier plate (1).

16. The method as claimed in claim 14, characterized in that the additional temporary carrier plate (16) is separated from the anisotropic crystal plate (2) using a solvent.

17. The method as claimed in claim 16, characterized in that the additional temporary carrier plate (16) has openings through which the solvent can reach the thick cement layer (15).

18. A zeroth- or low-order phase delay element, in particular for use in projection objectives for semiconductor lithography, characterized by an isotropic carrier plate (8), which is directly connected to a crystal plate (2) comprising anisotropic crystal.

19. The phase delay element as claimed in claim 18, characterized by use at wavelengths λ<200 nm.

20. The phase delay element as claimed in claim 18, characterized in that the isotropic carrier plate (8) is formed from crystalline CaF₂ or amorphous SiO₂.

21. The phase delay element as claimed in claim 18, characterized in that the anisotropic crystal plate (2) is formed from MgF₂, SiO₂ or LaF₃.

22. The phase delay element as claimed in claim 18, characterized in that the isotropic carrier plate (8) has an antireflection coating layer (10) on a side that is not connected to the anisotropic crystal plate (2).

23. The phase delay element as claimed in claim 18, characterized in that an edge region of the anisotropic crystal plate (2) is provided with a resist layer (12).

24. The phase delay element as claimed in claim 18, characterized in that an adhesion layer (9) is provided between the isotropic carrier plate (8) and the anisotropic crystal plate (2).

25. The phase delay element as claimed in claim 24, characterized in that the adhesion layer is an oxidic adhesion layer.

26. The phase delay element as claimed in claim 25, characterized in that the adhesion layer contains SiO₂ or Al₂O₃.

27. The phase delay element as claimed in claim 18, characterized by the achieving of a crystal diameter or largest length extent of at least 100 000 times, in particular at least 250 000 times, the crystal thickness.
